(19) United States
(12) Patent Application Publication
(10) Pub. No.: US 2025/0370036 A1
(43) Pub. Date: Dec. 4, 2025

(54) METHOD OF LOADING SEMICONDUCTOR DEVICE WITH FINE BUMPS INTO INSERT

(71) Applicant: ATECO INC., Gunpo-si (KR)

(72) Inventors: Taek Seon LEE, Hwaseong-si (KR); Ho Nam KIM, Seongnam-si (KR); Sung Chul MOON, Gunpo-si (KR); Han Su BAE, Siheung-si (KR)

(21) Appl. No.: 19/057,714

(22) Filed: Feb. 19, 2025

(30) Foreign Application Priority Data
May 30, 2024 (KR) 10-2024-0070789
May 30, 2024 (KR) 10-2024-0070795
Jan. 24, 2025 (KR) 10-2025-0010849
Jan. 24, 2025 (KR) 10-2025-0011050

(51) Int. Cl. G01R 31/28

(52) U.S. Cl. CPC G01R 31/2893; G01R 31/2889; G01R 31/2891

(57) ABSTRACT

The method of loading the semiconductor device having the fine bumps into the insert according to an embodiment of the disclosure comprises: by a first vision module, capturing a bottom image of the semiconductor device picked up by a picker; by a second vision module, capturing a top image of the insert; and by the picker, loading the semiconductor device into the insert, based on the bottom image and the top image.

### CROSS REFERENCE TO RELATED APPLICATIONS

Priority to Korean patent application number 10-2024-0070789 filed on May 30, 2024, and Korean patent application number 10-2024-0070795 filed on May 30, 2024, and Korean patent application number 10-2025-0010849 filed on Jan. 24, 2025, and Korean patent application number 10-2025-0011050 filed on Jan. 24, 2025, the entire disclosure of which is incorporated by reference herein, is claimed.

### BACKGROUND OF THE INVENTION

### Field of the Invention

The disclosure relates to a method of loading a semiconductor device with fine bumps into an insert.

### Description of the Related Art

A high bandwidth memory (HBM) was originated due to a higher memory bandwidth generally required in high-performance applications of a computer and a graphics processing unit. The existing graphics double data rate (GDDR) memory technology has been widely used in high-performance graphics cards and systems, but has reached its limits due to increasing bandwidth requirements. Accordingly, memory manufacturers have demanded new technologies to provide a higher bandwidth and to process data more efficiently.

To meet such a demand, the HBM has adopted an innovative design of forming a memory chip stack. In the HBM, memory chips are stacked vertically to provide advantages of achieving a high bandwidth, taking up less space, and reducing power consumption. These advantages have provided a backdrop for the HBM to attract attention as the memory bandwidth and power efficiency become more import in high-performance computing and graphics processing systems.

Meanwhile, the HBM needs to be tested in a die state before packaging. The die of the HBM has many more contact portions than those of the existing memories, and many contact portions are provided at a fine pitch in a limited area. However, a conventional test handler had a problem in that fine pitch contact for testing the HBM was difficult.

### SUMMARY OF THE INVENTION

An aspect of the disclosure is to provide a method of aligning and loading devices having a fine pitch into an insert for a test.

The problems of the disclosure are not limited to the aforementioned problems, and other problems not mentioned above may become apparent to those skilled in the art from the following description.

According to an embodiment of the disclosure, a method of loading a semiconductor device with fine bumps into an insert relates to a method of loading a semiconductor, which has a plurality of fine bumps on a bottom surface, into an insert formed with guide grooves on a top surface to accommodate the fine bumps, respectively.

The method of loading the semiconductor device with the fine bumps into the insert comprises by a first vision module, capturing a bottom image of the semiconductor device picked up by a picker; by a second vision module, capturing a top image of the insert; and by the picker, loading the semiconductor device into the insert, based on the bottom image and the top image.

The loading the semiconductor device into the insert may include: identifying a position of a reference bump among the plurality of fine bumps in the bottom image; identifying a position of a reference groove to accommodate the reference bump therein among the plurality of guide grooves in the top image; identifying the amounts of movement and rotation for the semiconductor device, based on the position of the reference bump and the position of the reference groove; and moving the semiconductor device above the insert based on the identified amount of movement, and placing the semiconductor device in the insert in an aligned posture based on the identified amount of rotation.

In the step of the identifying the position of the reference bump, an actual position and posture of the semiconductor device may be identified based on the position of the reference bump on the bottom image.

In the step of the identifying the position of the reference groove, an actual position and posture of the insert to load the semiconductor device may be identified based on the position of the reference groove on the top image.

In the step of the identifying the position of the reference bump, the actual position of the semiconductor device may be identified based on the position of the reference bump on the bottom image and an accurately set capturing location of the first vision module.

In the step of the identifying the position of the reference groove, the actual position of the insert may be identified based on the position of the reference groove on the top image and an accurately set capturing location of the second vision module.

In the step of the identifying the amounts of movement and rotation for the semiconductor device, the amount of movement for the semiconductor device may be identified based on difference in coordinates between the actual position of the semiconductor device and the actual position of the insert.

In the step of the identifying the position of the reference bump, the actual posture of the semiconductor device may be identified based on a first angle of the reference bump shown in the bottom image to a reference point on the bottom image.

In the step of the identifying the position of the reference groove, the actual posture of the insert may be identified based on a second angle of the reference groove shown in the top image to a reference point on the top image.

In the step of the identifying the amount of movement and rotation for the semiconductor device, the amount of rotation for the semiconductor device may be identified based on difference between the first angle and the second angle.

The loading the semiconductor device into the insert may include: identifying a position of a dummy bump formed separately from the plurality of fine bumps in the bottom image; identifying a position of a groove for the dummy bump formed separately from the plurality of guide grooves to accommodate the dummy bump in the top image; identifying the amount of movement and rotation for the semiconductor device based on the position of the dummy bump and the position of the groove for the dummy bump; and moving the semiconductor device above the insert based on the identified amount of movement, and placing the semiconductor device in the insert in the aligned posture based on the identified amount of rotation.

In the step of the identifying the position of the dummy bump, an actual position and posture of the semiconductor device may be identified based on the position of the dummy bump on the bottom image.

In the step of the identifying the position of the groove for the dummy bump, an actual position and posture of the insert to load the semiconductor device may be identified based on the position of the groove for the dummy bump on the top image.

The dummy bump may be formed to be larger than the fine bump, and may include a lower portion shaped corresponding to the shape of the fine bump.

The dummy bump may be located outside an area where the plurality of fine bumps are located on the bottom surface of the semiconductor device.

The method may further include picking up a plurality of semiconductor devices by a plurality of pickers arranged in a predetermined array.

In the step of the capturing the bottom image by the first vision module, a bottom surface of a representative semiconductor device picked up by a representative picker among the plurality of pickers may be captured.

In the step of the identifying the amounts of movement and rotation for the semiconductor device, the amounts of movement and rotation for the remaining semiconductor devices may be identified based on the amount of movement and rotation for the representative semiconductor device.

In the step of the capturing the bottom image by the first vision module, the bottom image may be captured while lighting illuminates the bottom surface of the semiconductor device.

In the step of the capturing the top image by the second vision module, the top image is captured while lighting illuminates the top surface of the insert.

In the step of the placing the semiconductor device in the insert in the aligned posture, a holding member of the insert, by pressing the placed semiconductor device downward, may hold the position of the semiconductor device.

In the step of the placing the semiconductor device in the insert in the aligned posture, a floating board formed with the guide groove and the semiconductor device may be pressed to downward by the holding member, and an insert terminal accommodated inside the guide groove may be in contact with the fine bump moved downward.

Other specific details of the disclosure are included in the detailed description and the accompanying drawings.

### BRIEF DESCRIPTION OF THE DRAWINGS

FIG. 1 is a view showing a test tray that can be used in a method of loading a semiconductor device with fine bumps into an insert according to an embodiment of the disclosure.

FIG. 2 is a view showing an insert that can be used in a method of loading a semiconductor device with fine bumps into an insert according to an embodiment of the disclosure.

FIG. 3 is an exploded perspective view of the insert shown in FIG. 2.

FIG. 4 is a view schematically showing an electric contact portion that may be installed in the insert of FIG. 2.

FIG. 5 is a flowchart of a method of loading a semiconductor device with fine bumps into an insert according to an embodiment of the disclosure.

FIG. 6 is a view conceptually showing a pickup module and a vision module that can be used in a method of loading a semiconductor device with fine bumps into an insert according to an embodiment of the disclosure.

FIG. 7 is a flowchart for describing a first embodiment of a step where “a picker loads a semiconductor device into an insert” included in a method of loading the semiconductor device with fine bumps into the insert according to an embodiment of the disclosure.

FIG. 8 is a view showing that a bottom image is captured by a first vision module at a first capturing location, in the step where the picker loads the semiconductor device into the insert according to the first embodiment of the disclosure.

FIG. 9 is a view showing that a top image is captured by a second vision module at a second capturing location, in the step where the picker loads the semiconductor device into the insert according to the first embodiment of the disclosure.

FIG. 10 is a view illustratively showing a captured bottom image, in the step where the picker loads the semiconductor device into the insert according to the first embodiment of the disclosure.

FIG. 11 is a view illustratively showing a captured top image, in the step where the picker loads the semiconductor device into the insert according to the first embodiment of the disclosure.

FIG. 12 is a view showing that the semiconductor device is moved having an aligned posture to an upper side of the insert, in the step where the picker loads the semiconductor device into the insert according to the first embodiment.

FIG. 13 is a view showing that the picker is in close contact with the upper side of the insert according to an embodiment of the disclosure.

FIG. 14 is a view showing that the semiconductor device is seated on a floating board after the insert is switched over to an open state according to an embodiment of the disclosure.

FIG. 15 is a view showing that the insert is switched over to a closed state after the picker loads the semiconductor device according to an embodiment of the disclosure.

FIG. 16 is a flowchart for describing a second embodiment of a step where “a picker loads a semiconductor device into an insert” included in a method of loading the semiconductor device with fine bumps into the insert according to an embodiment of the disclosure.

FIG. 17 is a view showing that a bottom image is captured by a first vision module at a first capturing location, in the step where the picker loads the semiconductor device into the insert according to the second embodiment of the disclosure.

FIG. 18 is a view showing that a top image is captured by a second vision module at a second capturing location, in the step where the picker loads the semiconductor device into the insert according to the second embodiment of the disclosure.

FIG. 19 is a view conceptually showing a captured bottom image in the step where the picker loads the semiconductor device into the insert according to the second embodiment of the disclosure.

FIG. 20 is a view illustratively showing a captured top image in the step where the picker loads the semiconductor device into the insert according to the second embodiment of the disclosure.

### DETAILED DESCRIPTION OF THE INVENTION

The merits and characteristics of the disclosure and a method for achieving the merits and characteristics will become more apparent from embodiments described below in detail in conjunction with the accompanying drawings. However, the disclosure is not limited to the disclosed embodiments, but may be implemented in various different ways. The embodiments are provided to only complete the disclosure and to allow those skilled in the art to understand the category of the disclosure. The disclosure is defined by the category of the claims.

In addition, embodiments of the disclosure will be described with reference to cross-sectional views and/or schematic views as idealized exemplary illustrations. Therefore, the illustrations may be varied in shape depending on manufacturing techniques, tolerance, and/or etc. Further, elements in the drawings may be relatively enlarged or reduced for convenience of description. Like numerals refer to like elements throughout.

A “semiconductor device” to be mentioned below refers to a semiconductor product with a plurality of bumps arranged at a fine pitch on the bottom thereof. The semiconductor device may be a finished product or a semi-finished product. For example, the semiconductor device may be a high bandwidth memory (HBM). Further, a bump refers to a terminal protruding from the bottom of the semiconductor product.

Further, up/down/front/back/left/right directions to be mentioned below are merely to describe the positions of elements compared to a certain reference point for easy understanding, but the disclosure is not limited to those directions. For example, it is obvious that installation and/or operation directions set forth herein may be modified in actual use and the disclosure may be interpreted to include such embodiments.

Further, the coordinates of a groove/bump to be mentioned below may include the central or boundary coordinates of a groove/bump, or the coordinates of a point representing the groove/bump set as a specific reference by a user in advance.

Below, a method of loading a semiconductor device with fine bumps into an insert according to an embodiment of the disclosure will be described with reference to the accompanying drawings.

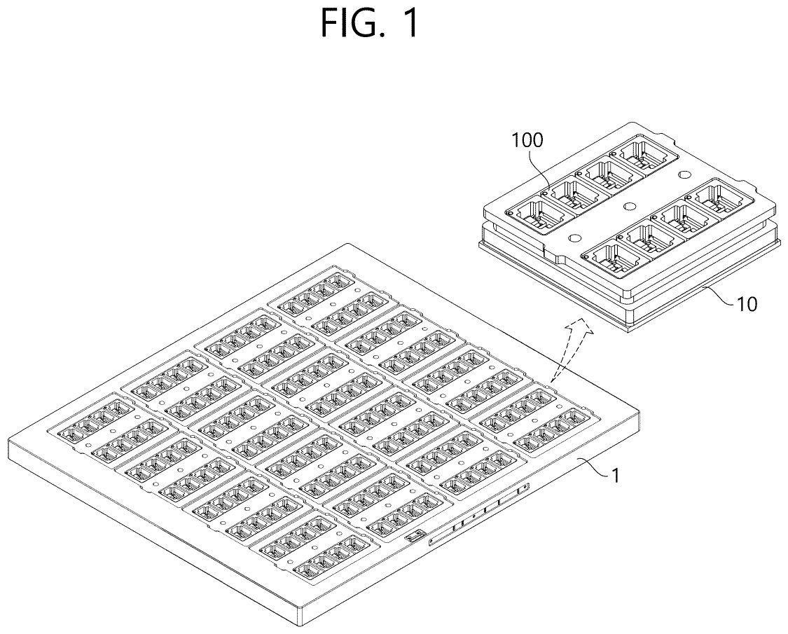

To help understanding, a test tray and an insert that can be used in a method of loading a semiconductor device with fine bumps into the insert according to an embodiment of the disclosure will be first described with reference to FIGS. 1 to 4.

FIG. 1 is a view showing a test tray that can be used in a method of loading a semiconductor device with fine bumps into an insert according to an embodiment of the disclosure.

Referring to FIG. 1, a test tray 1 that can be used in an embodiment of the disclosure is configured to be transported with a plurality of semiconductor devices loaded into an insert 100. The plurality of semiconductor devices is configured to undergo a test while being loaded into the insert 100 and seated on a test device. The test may be carried out on equipment called a ‘handler’, which tests the performance of the semiconductor device under specific temperature conditions and classify the semiconductor device according to grades. A method of using the handler to test the semiconductor device has conventionally been publicly known, and thus descriptions thereof will be omitted.

A plurality of inserts 100 may be provided on a plurality of sub-trays 10 provided in the test tray 1. The plurality of sub-trays 10 may be detachably coupled to the test tray 1. As necessary, one or more sub-trays 10 may undergo the test while being coupled to the test tray 1.

If necessary, the test tray 1 stands by in a separate place, and only the sub-tray 10 may be transported to a location where the semiconductor device is loaded or unloaded. The sub-tray 10 may be coupled to the test tray 1 after the semiconductor device to be tested is loaded into the insert 100, or may be separated from the test tray 1 and transported separately to unload the semiconductor device that has been tested. In this case, well-known optional fastening elements may be applied to coupling and separation between the sub-tray 10 and the test tray 1.

The sub-tray 10 is configured to couple with a predetermined number of inserts 100. The semiconductor device may be loaded into each of the inserts 100. The loaded semiconductor devices may be in electrical contact with the insert 100. Further, each of the inserts 100 may be electrically connected to a board that forms the bottom of the sub-tray 10. To this end, the board forming the bottom of the sub-tray 10 may have a tray terminal to be electrically connected to the insert 100. The tray terminal may be formed on the bottom of the sub-tray 10, where each insert 100 is seated.

Further, the tray terminal may be electrically connected to a test terminal formed on the bottom of the sub-tray 10. When the test tray 1 is seated on the test device, the socket and test terminal of the test device are electrically contacted, thereby electrically connecting the insert 100 to the test device. Ultimately, the semiconductor devices may be electrically connected to and exchange signals with the test device through the insert 100 and the sub-tray 10.

However, the foregoing configuration of the sub-tray may be applied selectively. As an example, the sub-tray may be omitted and a plurality of insert modules may come into direct contact with the test tray 1. Alternatively, the sub-tray itself may be used as the test tray.

The insert 100 is configured to reliably secure the position of the semiconductor device during the transportation and/or testing of the test tray 1. When the semiconductor device is secured to the insert 100, the bumps of the semiconductor device may come into electrical contact with electrical contact means of the insert 100, respectively.

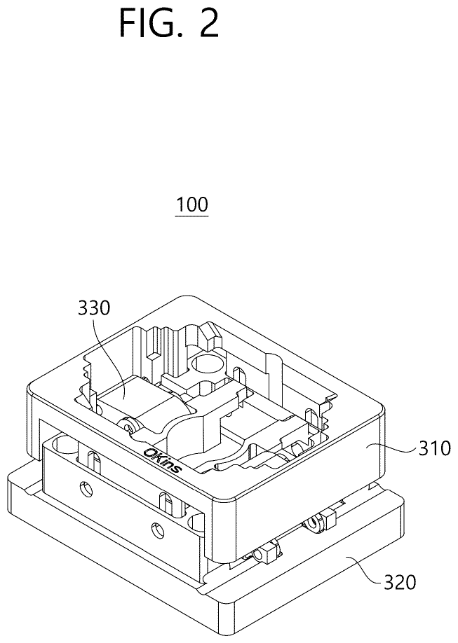

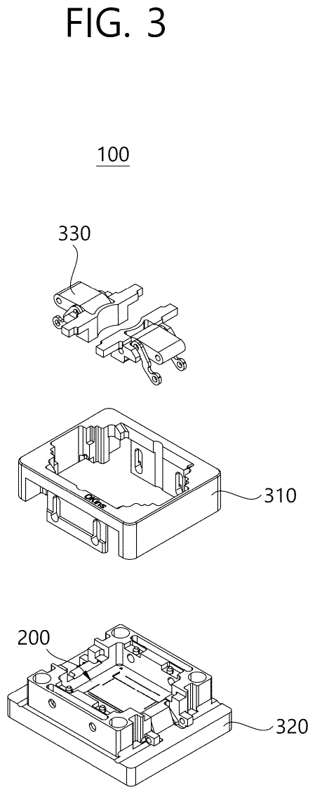

Continuing the description with reference to FIGS. 2 and 3, FIG. 2 is a view showing an insert that may be used in a method of loading a semiconductor device with fine bumps into an insert according to an embodiment of the disclosure. Further, FIG. 3 is an exploded perspective view of the insert shown in FIG. 2.

As shown in FIGS. 2 and 3, the insert 100 applicable to an embodiment of the disclosure may include an upper block 310, a lower block 320, a holding member 330, and an electric contact portion 200.

The upper block 310 may be configured to couple with the lower block 320 in up and down directions. In this case, the upper block 310 may be provided to move up and down by a predetermined height relative to the lower block 320 in a coupling state. Although not shown, a publicly known elastic member may be provided between the upper block 310 and the lower block 320 to elastically support the upper block 310 with respect to the lower block 320. For example, the elastic member may include a coil spring.

Meanwhile, the holding member 330 may be configured to adjust a pivot angle to the lower block 320 depending on a gap between the upper block 310 and the lower block 320. For example, the holding member 330 may have a lower end divided into two branches so that the angle can be adjusted according to the height of the upper block 310. One of the branched end portions may be angle-adjustably coupled to the upper block 310, and the other may be angle-adjustably coupled to the lower block 320.

With this structure, a free end of the holding member 330 may be rotated as much as possible in a downward direction of the insert 100 while the upper block 310 is moved up as much as possible. In this state, the free end of the holding member 330 may press the top surface of the semiconductor device loaded into the insert 100 downward. On the other hand, when the upper block 310 is moved down as much as possible, the free end may be rotated in a direction to come into maximum contact with the inner wall of the insert 100. In this state, a gap between the holding members 330 forming a pair becomes larger than the width of the semiconductor device, thereby allowing the semiconductor device to be withdrawn from the insert 100.

The holding members 330 may be provided as a pair and configured symmetrically, and a gap therebetween may form a circular space when the upper block 310 is raised to a closed state as much as possible. To this end, the free end of the holding member 330 may be recessed to have a semicircular concave shape.

Meanwhile, the electric contact portion 200 may be configured to come into electrical contact with the semiconductor device loaded into the insert 100 in a state that the holding member 330 presses the semiconductor device (i.e., a closed state). The electric contact portion 200 may have an upper surface that forms the bottom of the lower block 320 (i.e., the surface on which the semiconductor device is seated), and a lower surface that forms the bottom of the insert 100 (i.e., a surface to be seated on the sub-tray). While the insert 100 is coupled to the sub-tray, the electric contact portion 200 may be in electrical contact with the tray terminal formed on the board through the terminal exposed to the lower end.

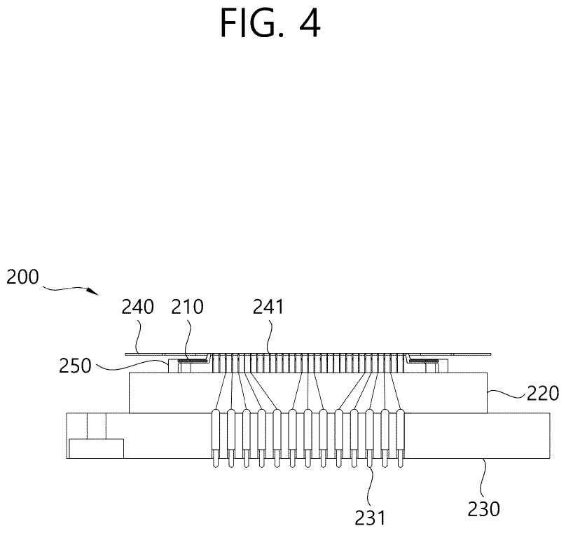

Below, the electric contact portion according to an embodiment of the disclosure will be described with reference to FIG. 4. FIG. 4 is a view schematically showing an electric contact portion that may be installed in the insert of FIG. 2.

As shown in FIG. 4, the electric contact portion according to an embodiment of the disclosure 200 may include a floating board 240, a terminal board 250, a circuit board 220, and a holding board 230.

The floating board 240 may be a plate-shaped member that provides a surface on which the semiconductor device is seated in the insert. The floating board 240 may be provided to be height-adjustable with respect to the terminal board 250 above the terminal board 250. Although not shown, the floating board 240 may be elastically supported by various conventionally known elastic members. For example, an elastic member that elastically supports the floating board 240 upward may be disposed between the floating board 240 and the terminal board 250. Alternatively, considering a narrow gap between the floating board 240 and the terminal board 250, the elastic member may be disposed between the floating board 240 and the circuit board 220. In this case, the floating board 240 and the circuit board 220 may be larger than the terminal board 250. For example, the elastic member may be a coil spring.

Meanwhile, the floating board 240 may be formed to be slightly smaller than a pocket of the upper block. Here, the pocket may refer to an internal space of the upper block. Therefore, the floating board 240 may be slightly shaken not only in the up and down directions but also in the horizontal directions of forward, backward, left and right directions while being elastically supported. This shaking motion may allow a guide groove 241 to be finely aligned with and move with respect to the fine bumps in the process of seating the semiconductor device on the floating board 240.

Meanwhile, a plurality of guide grooves 241 may be perforated on the top of the floating board 240 to respectively accommodate the fine bumps formed on the bottom of the semiconductor device. The guide groove 241 may be formed to have a size and depth corresponding to those of the fine bump, and may be shaped to have a constant inner diameter in an upper portion and a smaller inner diameter in a deeper lower portion. In this case, the deepest portion of the guide groove 241 may be have an inner diameter of approximately 0.2 mm. An insert terminal 210 of the terminal board 250 may be accommodated in the guide groove 241.

The terminal board 250 may be disposed below the floating board 240, and include a plurality of insert terminals 210 protruding upward from the top surface thereof. Further, the terminal board 250 may expose the lower end of the insert terminal 210 to the bottom.

The number of insert terminals 210 may correspond to the number of fine bumps, and may be each inserted into the guide groove 241. The insert terminal 210 may be accommodated in the deep lower portion of the guide groove 241 in an open state where the semiconductor device is not pressed by the holding member. When the insert is switched over to a closed state, the floating board 240 pressed by the holding member moves down, and the upper end of the insert terminal 210 moves up relative to the floating board 240 to a height adjacent to the top of the guide groove 241. Due to this, the insert terminal 210 may be in electrical contact with the fine bumps accommodated in the guide groove 241.

Meanwhile, the circuit board 220 may be placed below the terminal board 250. A pitch expansion circuit to come into electrical contact with the lower end of the insert terminal 210 may be formed on the circuit board 220. In this case, a distance between contact points (hereinafter referred to as top contact terminals) located on the top surface of the circuit board 220 in the pitch expansion circuit may correspond to a distance between the insert terminals 210. Further, a distance between contact points (hereinafter referred to as bottom contact terminals) extending from the top contact terminals and exposed to the bottom of the circuit board 220 may have a distance longer than the distance between the top contact terminals.

Meanwhile, the holding board 230 refers to a board including an external terminal 231 electrically connected to the bottom contact terminal, which may be a plate-shaped member forming the bottom of the insert. The distance between the external terminals 231 may be similar to the distance between the bottom contact terminals. The external terminal 231 may have an upper end exposed to the top of the holding board 230, and a lower end exposed to the bottom of the holding board 230. The upper end of the external terminal 231 may be in electrical contact with the bottom contact terminal. In this regard, the lower end of the external terminal 231 may come into electrical contact with the tray terminal or electrical contact with the socket of the test device.

With this structure, the insert used according to the disclosure has an advantage that the space between the terminals formed in the socket may be wider than the space between the bumps of the semiconductor device.

Below, based on the foregoing description, a method of loading a semiconductor device with fine bumps into an insert according to an embodiment of the disclosure will be described. For the convenience of description, the same or similar elements as described above will be given the same reference numerals, and redundant descriptions thereof will be avoided.

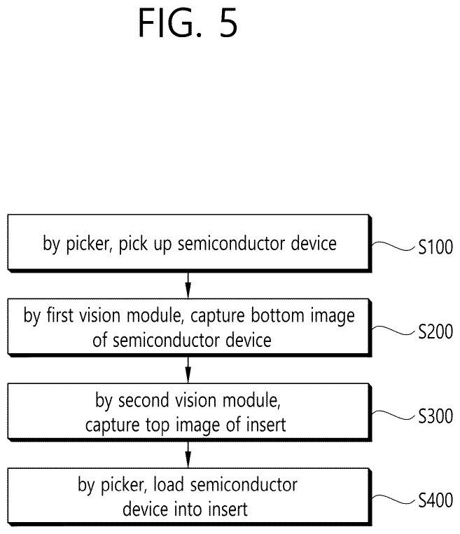

FIG. 5 is a flowchart of a method of loading a semiconductor device with fine bumps into an insert according to an embodiment of the disclosure.

As shown in FIG. 5, a method of loading a semiconductor device with fine bumps into an insert according to an embodiment of the disclosure may include the steps of: by a picker, picking up the semiconductor device (S100); by a first vision module, capturing a bottom image of the semiconductor device (S200); by a second vision module, capturing a top image of the insert (S300); and by the picker, loading the semiconductor device into the insert (S400).

In the step S100 where the picker picks up the semiconductor device, the picker configured to pick and place the semiconductor device picks up the semiconductor device. In this case, the picker may be provided in the handler and transported from a pickup position to a placing position for the semiconductor device. In this case, the placing position may refer to a position where the sub-tray, the test tray and/or the insert described above stand by to be loaded with the semiconductor device.

For example, the picker may be configured to hold the semiconductor device based on pneumatic pressure. For example, the picker may include a suction cup in a lower portion thereof, and may be provided to suck and hold the semiconductor device by providing negative pressure while the suction cup is in close contact with the semiconductor device. The picker may be based on conventionally known technologies, and detailed descriptions thereof will be omitted.

In this step, the picker may pick up at least one semiconductor device at the pickup position. In this case, the semiconductor devices picked up at once may be loaded into the same sub-tray. Meanwhile, a user may set the operations of the picker so that the picker can picks up the exact center of the semiconductor device in this stage. However, these operations are ideal, and errors occur actually when the semiconductor device is transported to the pickup position and picked up by the picker. Due to these errors, the actual position and posture of the picker that is picking up the semiconductor device may differ slightly from the ideal prediction.

To help understanding, the pickup position refers to a position where the picker driven by a driving device inside the system performs the pickup operation, and the pickup position may be set in advance based on accurate coordinates. Therefore, the pickup position may always be the same. The semiconductor device being picked up may be loaded into the pickup position in advance. In this case, ideally, the prepared semiconductor devices should be located at the pickup position without errors, but it is very difficult to always transport the semiconductor devices without any error during the transportation process.

Such a slight error does not cause a problem in picking up the semiconductor device during the pickup operation of the picker at the pickup position. However, these errors may cause the actual position and posture of the semiconductor device picked up by the picker to be slightly changed on each occasion.

Meanwhile, the bottom of the semiconductor device, from which the fine bumps protrude, may be exposed downward while being picked up by the picker. In other words, the picker may hold and pick up the top surface of the semiconductor device.

In the step S200 where the first vision module captures the bottom image of the semiconductor device, the first vision module may capture the bottom image by photographing the bottom of the semiconductor device picked up by the picker. To this end, the first vision module may include a camera module for photographing and a lighting module for clear imaging. For example, the lighting module may include a coaxial lighting module that irradiates light coaxially with the optical axis of the camera, and/or a ring lighting module arranged in a ring shape surrounding the camera module.

Hereinafter, a position where the bottom image is captured by the first vision module will be referred to as a first capturing location. To efficiently form the picker's movement line, the first capturing location may be provided between the pickup position and the placing position. In this case, the first vision module may be arranged to face upward from below a path in which the picker moves from the pickup position to the placing position.

The picker may be set to stop for a moment to capture the bottom image when reaching the first capturing location. In this case, the first vision module is stationary without moving, so that a user can determine the coordinates of the first capturing location. In other words, the location of the first vision module is accurately specified within the system, and thus the first capturing location where the picker stops is accurately identified in advance. The first capturing location set in this way may be used to determine the actual position and posture of the semiconductor device through the bottom image.

Specifically, because the first vision module and the first capturing location are fixed, the same position in real space is always captured at the coordinates of the bottom image. To help understanding, a plane where the semiconductor device is located on the bottom image will be referred to as an XY plane. In this case, a subject located at the same coordinates on the XY plane in real space always appears at specific coordinates of the bottom image.

In the step S300 where the second vision module captures the top image of the insert, the second vision module photographs the insert from above the insert. Thus, in this step, the top image of the upper surface of the insert may be obtained. In this case, the top image may show the top surface of the upper block forming the top surface of the insert, the top surface of the floating board, and the top surface of the holding member. Alternatively, the top image may be captured by focusing on the floating board portion of the insert.

Similarly to the first vision module, the second vision module may include a camera module for photographing and a lighting module for clear imaging. For example, the lighting module may include a coaxial lighting module that irradiates light coaxially with the optical axis of the camera, and/or a ring lighting module arranged in a ring shape surrounding the camera module.

The second vision module may be provided to face the insert from above the insert that stands by in the placing position. For example, the second vision module may be arranged to reach the upper side of the insert in a path that intersects the picker, or may be arranged to move together with the picker.

Meanwhile, the placing position actually corresponds to the current position of the insert into which the semiconductor device will be loaded. Therefore, ideally, the placing position is always the same position set in the system. However, in the process of preparing the sub-tray and/or the insert, it is realistically very difficult to load the sub-tray and/or the insert into the same position on each occasion without any slightest error. Therefore, the actual placing position may vary slightly on each occasion.

In this regard, the position where the second vision module captures an image may always be the same specific position. This is because the second vision module is always moved to the same position due to the driving device inside the system. Hereinafter, the position to which the second vision module moves to photograph the insert will be referred to as a second capturing location. In other words, the second capturing location is accurately set by a user in advance, and the accurately set second capturing location may be used to determine the actual position and posture of the insert.

Specifically, like that of the bottom image, the specific coordinates on the top image always capture the same coordinates on the XY plane in real space, so that a user can determine the actual position and posture of the insert by looking at the appearance of the insert on the top image.

In the step S400 where the picker loads the semiconductor device into the insert, the actual position and posture of the semiconductor device and the actual position and posture of the insert are identified based on the bottom image and the top image, thereby placing the semiconductor device with an aligned posture in the insert. In this case, the aligned posture may refer to a posture in which the fine bumps formed on the semiconductor device can be respectively accommodated in the corresponding guide grooves formed on the insert.

Here, the actual position of the semiconductor device may be identified as the XY coordinates of a representative point the semiconductor device has at the first capturing location. For example, the representative point may be the central coordinates of the semiconductor device, at least one of the fine bumps of the semiconductor device, or a separate means for alignment.

Further, the actual posture of the semiconductor device may be expressed as a first angle which indicates how rotated the semiconductor device was when picked up. Information about the actual posture may be obtained through the location of the representative point shown in the bottom image. Meanwhile, to adjust the posture (angle) of the semiconductor device, the picker may be rotatable about a central axis while picking up the semiconductor device. The posture of the semiconductor device may be corrected based on the rotation of the picker.

The actual position of the insert represents the placing position and may be identified as the XY coordinate value of the representative point of the insert when shooting with the second vision module in the second capturing location. In this case, the representative point may be the central coordinates of the insert, at least one of the guide grooves of the insert, or a separate alignment means.

Further, the actual posture of the insert may be expressed as a second angle, which indicates how much the insert has been rotated. Information about the actual posture may be obtained based on the location of the representative point shown in the top image. In the foregoing example, the picker rotates the semiconductor device. Alternatively, a stage on which the sub-tray is seated may rotate instead of the picker.

In this step, loading the semiconductor device into the insert with the aligned posture may mean the following.

An information processing device capable of communication with the first vision module and the second vision module first receives the bottom image and the top image, and identifies the actual positions and postures of the semiconductor device and insert based on the received images. In this case, the information processing device may refer to a computing device in which a program set to execute each step included in the method according to an embodiment of the disclosure is non-transitorily recorded.

The information processing device identifies the amount of movement needed to move the semiconductor device directly above the insert and the amount of rotation needed to align the semiconductor device to be loaded into the insert. In this case, a state in which the semiconductor device is rotated with respect to the insert by the identified amount of rotation may be the aligned posture.

Then, the picker may move and rotate the semiconductor device on the XY plane based on the amounts of movement and rotation. Alternatively, the rotation may be implemented by a stage to rotate the insert itself, so that the semiconductor device can have the aligned posture with respect to the insert. In this case, the sequence of movement and rotation of the XY coordinates does not matter. In other words, the semiconductor device may first be moved by the amount of movement and then rotated by the amount of rotation. Conversely, the semiconductor device may be rotated by the amount of rotation and then moved by the amount of movement.

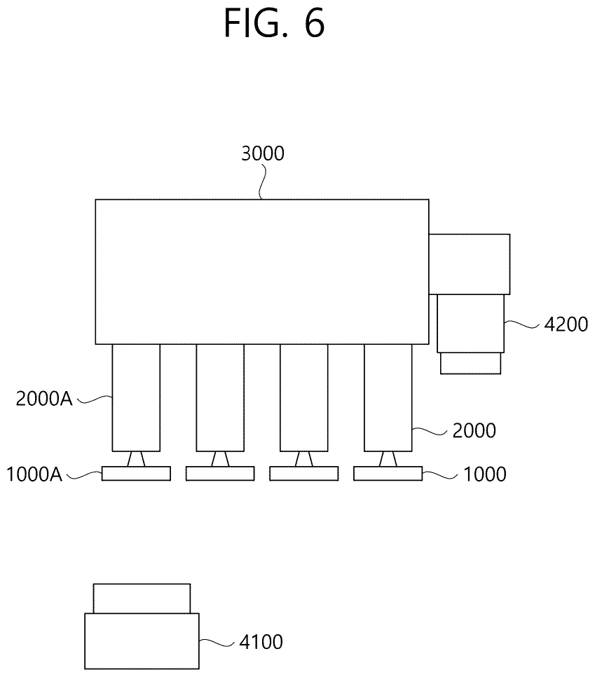

Below, a method of aligning a plurality of semiconductor devices all at once in a method of loading a semiconductor device with fine bumps into an insert according to an embodiment of the disclosure will be described with reference to FIG. 6. FIG. 6 is a view conceptually showing a pickup module and a vision module that may be used in a method of loading a semiconductor device with fine bumps into an insert according to an embodiment of the disclosure.

As shown in FIG. 6, a pickup module 3000 used in the disclosure may include a plurality of pickers 2000 so as to pick up multiple semiconductor devices 1000 at once. The pickup module 3000 is movable on the XY plane and movable up and down in the Z-axis direction based on the conventionally known structure. The pickup module 3000 may moves directly above the set pickup position and then moves down to pick up the multiple semiconductor devices 1000 located at the pickup position at once.

Meanwhile, the number and arrangement of pickers 2000 may be provided to correspond to the number and arrangement of inserts mounted to the sub-tray used in the system. For example, if the inserts are provided in an array of 2×4 as shown in FIG. 1, the same number and arrangement of pickers 2000 may also be mounted to the bottom of the pickup module 3000.

Therefore, if the pickup module 3000 shown in FIG. 6 is used in the method according to an embodiment of the disclosure, the plurality of pickers 2000 arranged in an array corresponding to the array of the inserts picks up the semiconductor devices 1000 at once in the step S100 where the picker picks up the semiconductor devices.

In this case, at the pickup position, the semiconductor devices 1000 stand by as being loaded onto a user tray formed corresponding to the sub-tray. The user tray may be formed with grooves in which the semiconductor devices 1000 are respectively loaded, and the grooves in the user tray may be spaced apart from each other having the same space as those between the pickers 2000 and/or between the inserts. Further, the groove on the user tray may have a shape matching the shape of the semiconductor device 1000. Thus, the semiconductor devices 1000 may be loaded into the user tray without shaking. Accordingly, the semiconductor devices 1000 located in one user tray may have the same error as each other in the pickup state. In other words, an error may occur when the user tray is placed crookedly in the pickup position, and such an error may occur equally in each of the loaded semiconductor device 1000.

Considering these features according to an embodiment of the disclosure, when using the pickup module 3000 shown in FIG. 6, the bottom image is captured only for the semiconductor device 1000A held by one of the pickers 2000A among the plurality of pickers 2000, and the same or similar amounts of movement and rotation based on the captured bottom image are applied for all the remaining pickers 2000 and semiconductor devices 1000. For example, the picker 2000A, which is used as the reference for the alignment, may be one of the pickers 2000 located at the frontmost or rearmost of the pickup module 3000. Hereinafter, to distinguish from the other pickers 2000, the picker 2000A, which is the reference for the alignment, will be referred to as a representative picker 2000A, and the semiconductor device 1000A held by the representative picker 2000A will be referred to as a representative semiconductor device 1000A.

In this case, in the step S200 where the first vision module captures the bottom image of the semiconductor device, the representative semiconductor device 1000A is moved to the first capturing location, and a first vision module 4100 captures the bottom of the representative semiconductor device 1000A. FIG. 6 illustrates that the first vision module 4100 and the representative picker 2000A are aligned in the first capturing location.

When the capturing of the first vision module 4100 is completed, the pickup module 3000 advances toward a place where the sub-tray is located. In this case, a second vision module 4200 may be provided in front of the pickup module 3000. Accordingly, the second vision module 4200 may move together with the pickup module 3000, but may move before the picker 2000. This structure naturally allows the second vision module 4200 to first reach the insert in the process of moving the picker 2000 to the placing position, thereby efficiently forming the movement line of the pickup module 3000.

When the second vision module 4200 reaches the set second capturing location, the pickup module 3000 stops again, and the second vision module 4200 may start the capturing. In this case, the second capturing location may be a position directly above a place where the insert into which the representative semiconductor device 1000A will be loaded is ideally located. Therefore, when using the pickup module 3000 of FIG. 6, the second vision module 4100 first reaches the second capturing location in the advance process of the pickup module 3000, and the second vision module naturally captures the top image of the insert (S300). Likewise, in this step, the top image of the insert into which the representative semiconductor device 1000A will be loaded may be obtained.

In the step S400 where the picker loads the semiconductor device into the insert, the amounts of movement and rotation for the representative semiconductor device 1000A to be inserted into the insert in an appropriate posture are identified. In this case, the information processing device identifies an additional amount of movement for the semiconductor device 1000A in consideration of a distance that the pickup module 3000 has already advanced passing the first capturing location.

In this case, the pickup position, the first capturing location and the second capturing location are set accurately, so that the information processing device can calculate the amount of XY movement based on difference between the coordinates of the representative semiconductor device 1000A in the bottom image and the coordinates of the insert in the top image. Alternatively, the information processing device may add an advanced distance of the pickup module 3000 to the coordinates of the representative semiconductor device 1000A in the bottom image, and calculate a distance the representative semiconductor device 1000A needs to additionally move to reach the insert in the top image.

Meanwhile, the remaining semiconductor devices 1000 held at once have the same or similar errors as the representative semiconductor device 1000A, and thus need to be adjusted according to the same or similar amounts of movement and rotation to those for the representative semiconductor device 1000A. In this case, all the pickers 2000 are mounted to one pickup module 3000 at predetermined intervals, and thus the remaining semiconductor devices 1000 also move by the same amount as that of the representative semiconductor device 1000A in the process of aligning the representative semiconductor device 1000A with the corresponding insert. Then, when the representative picker 2000A and the other pickers 2000 are rotated by the amount of rotation, all the semiconductor devices 1000 become aligned with the corresponding inserts. Then, the pickup module 3000 moves down to load the plurality of semiconductor devices 1000 on the sub-tray, thereby completing the loading operation.

In the foregoing example, the alignment operation for all the semiconductor devices 1000 is performed based on that of one representative semiconductor device 1000A. However, the disclosure is not necessarily limited to this example. In other words, in principle, the picker may be set to perform the alignment operation individually for each of all the semiconductor devices 1000A. In other words, the case of aligning the remaining semiconductor devices 1000 based on the representative semiconductor device 1000A may be restrictively used only in some cases where the semiconductor devices 1000 have the same or similar loading errors.

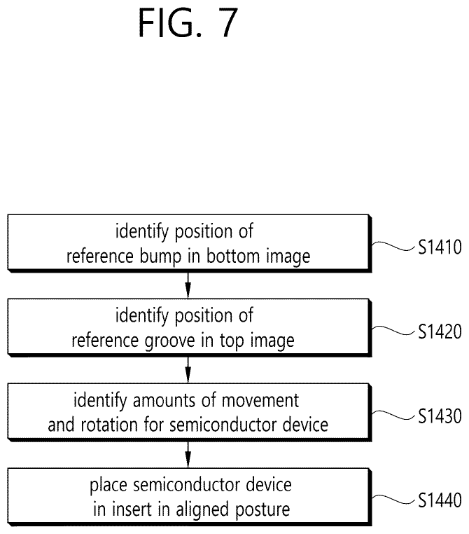

Below, a first embodiment of the step S400 where the picker loads the semiconductor device into the insert will be described with reference to FIGS. 7 to 12. FIG. 7 is a flowchart for describing a first embodiment of a step where “a picker loads a semiconductor device into an insert” included in a method of loading the semiconductor device with fine bumps into the insert according to an embodiment of the disclosure.

As shown in FIG. 7, the step where the picker loads the semiconductor device into the insert according to the first embodiment includes the steps of: identifying the position of a reference bump in the bottom image (S1410); identifying the position of a reference groove in the top image (S1420); identifying the amounts of movement and rotation for the semiconductor device (S1430); and placing the semiconductor device in the insert in the aligned posture (S1440).

First, in the step S1410 where the position of the reference bump is identified in the bottom image, the position of the reference bump among the plurality of fine bumps is identified in the bottom image. As described above, the plurality of bumps (or terminals) may protrude from the bottom of the semiconductor device. A user may set a fine bump, which is easy for the information processing device to identify among the fine bumps in the bottom image, as the reference bump. For example, the reference bump may be set based on the fine bump located at a corner among the plurality of fine bumps.

In this step, the information processing device recognizes the reference bump in the bottom image, thereby identifying the actual position of the semiconductor device. In other words, in this embodiment, the position of the semiconductor device may be specified through the position of the reference bump. In this case, an algorithm for recognizing a specific subject in an image has been already disclosed, and therefore descriptions thereof will be omitted. Meanwhile, it is not necessary to set only one reference bump, and multiple reference bumps may be set. In this case, the information processing device in this step may identify the positions of all the reference bumps identifiable in the bottom image.

Meanwhile, even if some of the reference bumps are not recognizable, the information processing device may process the subsequent steps based on the recognized reference bumps. Further, even if any of the recognized reference bumps is incorrectly recognized, the information processing device may ignore information about the incorrectly recognized reference bump and process the subsequent steps based on the correctly recognized reference bumps.

In this case, whether the reference bump was recognized incorrectly may for example be identified based on a distance from other members. For example, if the distance between the outer boundary of the semiconductor device or a specific member to a feature point and the reference bump has previously been recorded in the information processing device, the information processing device may identify that only the reference bumps located within a predetermined distance range from such a reference point have been correctly recognized. On the other hand, if the recognized reference bumps are located outside the predetermined distance range, the information processing device may ignore those reference bumps.

As another example, information about a distance from the central point of the semiconductor device to the point where the reference bump is located may be recorded in the information processing device. In this case, if the distance between the actually recognized reference bump and the central point differs from the recorded distance information by a predetermined value, it may be identified that the reference bump has been recognized incorrectly.

In the step S1420 where the position of the reference groove is identified in the top image, the position of the reference groove among a plurality of guide grooves is identified in the top image. In this case, the reference groove may be a guide groove, in which the reference bump will be accommodated, among the guide grooves.

In this step, the information processing device recognizes the reference groove in the top image and identifies the actual position of the insert. In other words, according to this embodiment, the position of the insert may be specified based on the position of the reference groove. In this case, identifying the position of the reference groove inside the insert or floating board in the top image may be achieved by the known algorithm like identifying the position of the reference bump in the bottom image, and thus redundant descriptions thereof will be omitted.

The information processing device may be set to find the reference bumps, the number of which corresponds to the number of reference grooves, and, if there are the reference grooves recognized incorrectly, ignore the incorrectly recognized groove. Further, the suitability for the recognition of the reference groove may also be identified based on a distance between the previously recorded reference groove and the central point of the floating board, a distance between the reference groove and other specific members to the feature point of the insert, etc.

In this case, the information processing device may identify only the positions of the reference grooves corresponding to the reference bumps recognized as suitable. If there is no reference groove corresponding to the reference bump suitably recognized in the previous step among the reference grooves recognized in this step, the step S300 of capturing the top image may be performed again.

In this case, the reference bump and the reference groove that correspond to each other may be identified based on comparison between the position of the reference bump with respect to the central coordinates of the semiconductor device shown in the bottom image and the position of the reference groove with respect to the central coordinates of the floating board shown in the top image. For example, the reference bump and the reference groove spaced apart by similar locations from the central coordinates may be identified to correspond to each other.

In the step S1430 where the amounts of movement and rotation for the semiconductor device are identified, the amounts of movement and rotation are identified based on the position of the reference bump and the position of the reference groove. In this step, the amount of movement for the picker may be identified based on the coordinates of the reference bump on the bottom image and the coordinates of the reference groove on the top image. Further, in this step, it is determined how much the semiconductor device should to be further rotated to reach the aligned posture with the insert, based on the posture of the semiconductor device on the bottom image and the posture of the insert on the top image. In other words, the amount of rotation may refer to an angle by which the semiconductor device should be relatively rotated so that the angle of the reference groove to the central coordinates of the insert on the top image and the angle of the reference bump to the center of the semiconductor device can be equal to each other.

In the step S1440 in which the semiconductor device is placed in the insert in the aligned posture, the picker transports the semiconductor device above the insert based on the identified amount of movement and rotation, rotates the semiconductor device, and then moves the semiconductor device downward to be loaded into the insert. In this case, as described above, the picker may be first rotated by the amount of rotation and then moved by the amount of movement, and not the picker but the stage supporting the sub-tray may be rotated.

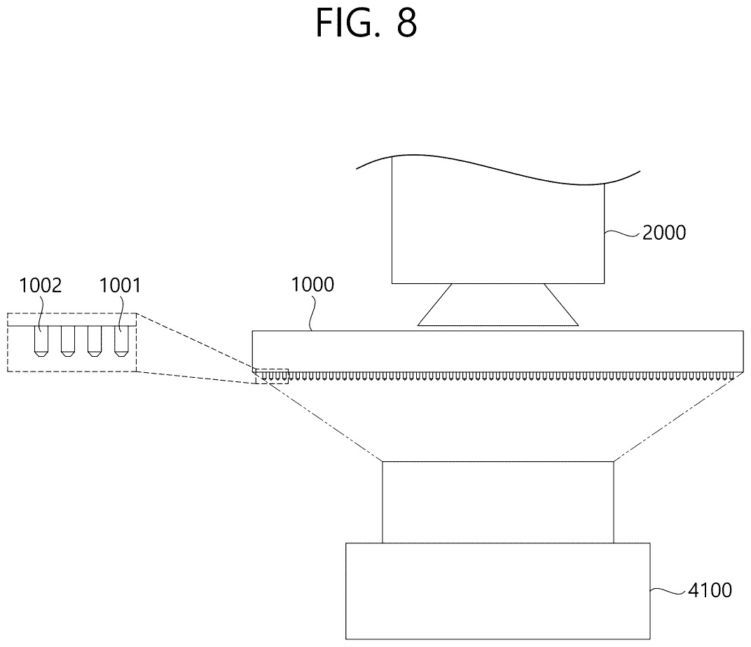

Below, continuing the description with reference to FIG. 8, FIG. 8 is a view showing that a bottom image is captured by a first vision module at a first capturing location, in step the where the picker loads the semiconductor device into the insert according to the first embodiment of the disclosure.

As shown in FIG. 8, a plurality of fine bumps 1001 protrude from the bottom of the semiconductor device 1000, and some of them may be set as the reference bump 1002. While the semiconductor device 1000 is held on the picker 2000, the bottom of the semiconductor device 1000 may be captured by the first vision module 4100.

In this case, the first vision module 4100 may use coaxial lighting and/or ring lighting to illuminate the bottom of the semiconductor devices 1000 by light, in order to prevent shadows from occurring in the bottom image due to a height difference caused by the fine bumps 1001 on the bottom of the semiconductor device 1000. Thus, an image obtained in the step S200 where the first vision module captures the bottom image of the semiconductor device may have a minimum dark area due to the shadows in the image. This lighting may have an effect on ensuring a good recognition rate of the reference bump 1001.

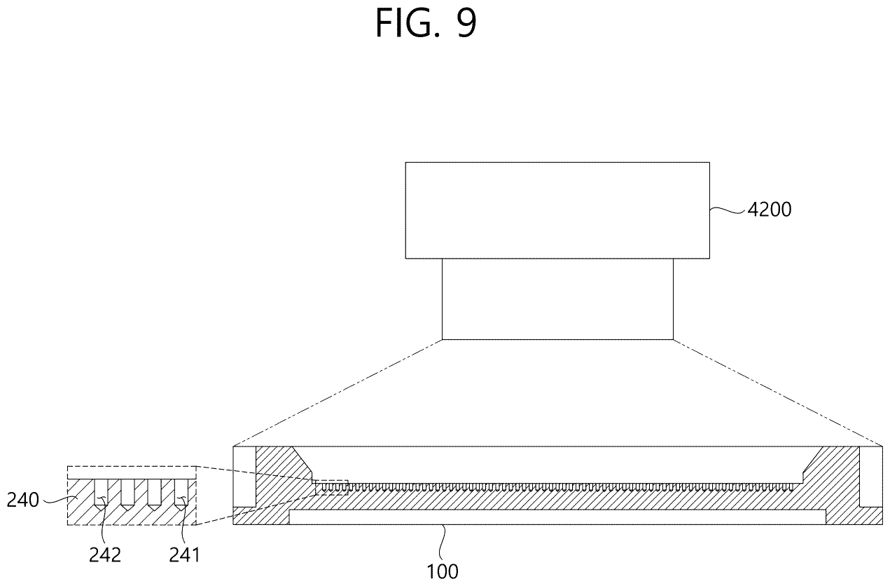

Meanwhile, FIG. 9 is a view showing that a top image is captured by a second vision module at a second capturing location, in the step where the picker loads the semiconductor device into the insert according to the first embodiment of the disclosure.

As shown in FIG. 9, the plurality of guide grooves 241 are formed on the upper surface of the floating board 240 of the insert 100, and a guide groove 242 located at a position corresponding to the reference bump among the plurality of guide grooves 241 may be set as the reference groove 242. The guide grooves 241 may be formed to be sized respectively corresponding to the fine bumps, and may be formed to have a gradually narrowed inner diameter of the lower end thereof so that the positions of the fine bumps can be aligned in the seating process.

Meanwhile, in the step S300 where the second vision module captures the top image of the insert, the second vision module 4200 may capture the top image while illuminating the insert 100, so that the guide groove 241 can be clearly shown on the top image. For example, the second vision module 4200 may use coaxial lighting and/or ring lighting to illuminate the upper surface of the floating board 240. Thus, the guide grooves 241 may appear clearly in the top image without being hidden by shadows or the like. This lighting may have an effect on ensuring a good recognition rate for the reference groove 242.

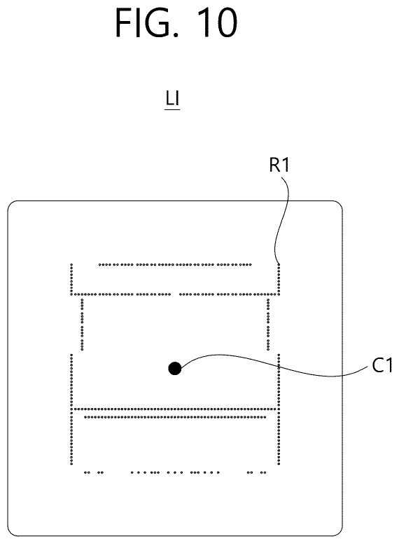

Below, an example of how to identify the actual position and posture of the semiconductor device based on the reference bump will be described with reference to FIG. 10. FIG. 10 is a view illustratively showing a captured bottom image, in the step where the picker loads the semiconductor device into the insert according to the first embodiment of the disclosure.

As described above, the information processing device may identify the actual position and posture of the semiconductor device based on a position of the reference bump R1 shown in a bottom image LI. A center point C1 of the bottom image LI has the same X and Y coordinates as those of the optical axis of the first vision module. Further, the coordinates of the bottom image LI always have the same X and Y coordinates in real space. This is because the first capturing location is always the same. Therefore, the coordinates the position of the reference bump R1 has on the bottom image LI allow the coordinates of the semiconductor device to be identified in real space.

In other words, according to the disclosure, only the coordinates of the reference bump R1, or only the location within the image of the mark identifiable by the separately prepared information processing device is enough to identify the actual position of the semiconductor device.

Meanwhile, the information processing device may recognize the first angle, which the reference bump R1 has with respect to a predetermined reference point shown in the bottom image LI, as the actual posture of the semiconductor device. For example, the reference point may be set as the central coordinates of the semiconductor device shown in the bottom image LI. In this case, the first angle may refer to an angle between a straight line connecting the coordinates of the reference bump R1 and the central coordinates of the semiconductor device and a straight line having a slope of ‘0’. For example, the first angle may be identified based on the slope of a straight line connecting the coordinates of the reference bump R1 and the central coordinates of the semiconductor device.

In this case, the central coordinates of the semiconductor device may be identified by publicly known methods. For example, the information processing device may recognize the boundary points of the semiconductor device shown in the bottom image LI and average the coordinates of the corresponding points, thereby obtaining the central coordinates. Alternatively, the semiconductor device may be marked with a separate mark to identify the central coordinates.

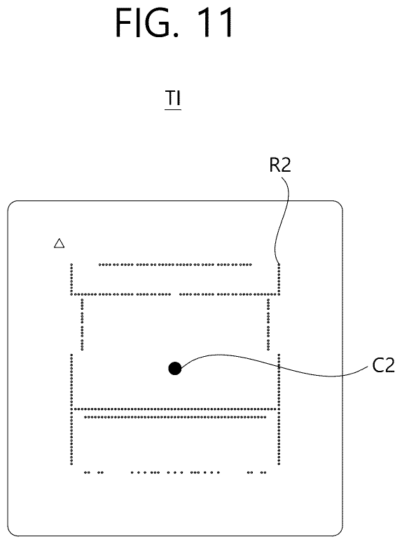

Below, an example of how to identify the actual position and posture of the insert based on the reference groove will be described with reference to FIG. 11. FIG. 11 is a view illustratively showing a captured top image, in the step where the picker loads the semiconductor device into the insert according to the first embodiment of the disclosure.

The information processing device may identify the actual position and posture of the insert based on the position of the reference groove R2 shown in the top image TI. The center point C2 of the top image TI has the same X and Y coordinates as the optical axis of the second vision module. Further, the coordinates of the top image TI always have the same X and Y coordinates in real space. This is because the second capturing location is always the same. Therefore, the coordinates the position of the reference groove R2 has on the top image TI allow the coordinates of the insert to be identified in real space.

In other words, according to the disclosure, only the coordinates of the reference groove R2, or only the location within the image of the mark identifiable by the separately provided information processing device is enough to identify the actual position of the insert.

Meanwhile, the information processing device may recognize the second angle, which the reference groove R2 has with respect to a predetermined reference point shown in the top image TI, as the actual posture of the insert. For example, the reference point may be set as the central coordinates of the insert and/or floating board (hereinafter referred to as the central coordinates of the insert) shown in the top image TI. In this case, the second angle may refer to an angle between a straight line connecting the coordinates of the reference groove R2 and the central coordinates of the insert and a straight line having a slope of ‘0’. For example, the second angle may be identified based on the slope of a straight line connecting the coordinates of the reference groove R2 and the central coordinates of the insert.

In this case, the central coordinates of the insert may be identified by publicly known methods. For example, the information processing device may recognize the boundary points of the insert and/or floating board shown in the top image TI and average the coordinates of the corresponding points, thereby obtaining the central coordinates. Alternatively, the insert and/or the floating board may be marked with separate marks to identify the central coordinates.

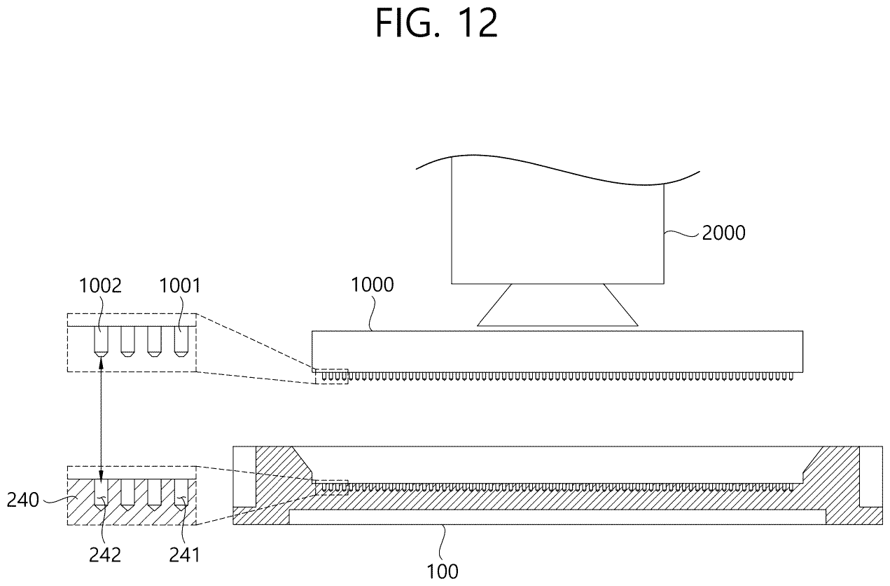

Below, a method of moving the semiconductor device above the insert in the aligned posture according to the first embodiment of the disclosure will be described with reference to FIG. 12. FIG. 12 is a view showing that the semiconductor device is moved having an aligned posture to an upper side of the insert, in the step where the picker loads the semiconductor device into the insert according to the first embodiment.

The amount of movement of the semiconductor device 1000 is identified based on difference between the actual position of the reference bump 1002 identified in the bottom image and the actual position of the reference groove 242 identified in the top image on the XY plane.

For example, to identify the amount of movement, the information processing device calculates the difference between the coordinates of the reference bump 1002 shown in the bottom image and the coordinates of the reference groove 242 shown in the top image, and then converts the calculated difference into a distance value in real space. Then, the information processing device may add the distance value in real space to the amount of originally required movement, thereby finally identifying the amount of movement. In this case, the amount of originally required movement refers to the amount of movement that the picker 2000 is required to move when the semiconductor devices 1000 and the insert 100 are in ideal positions.

As another example, the information processing device converts the position of the reference bump 1002 shown in the bottom image into the XY coordinates in real space, and converts the position of the reference groove 242 shown in the top image to XY coordinates in real space, thereby calculating the amount of movement based on the difference between the converted coordinates. In this case, the difference in distance between the first capturing location and the second capturing location may be subtracted from the amount of movement.

Meanwhile, when the semiconductor device 1000 is required to rotate, the information processing device may first reflect an XY coordinate change value based on the rotation in the amount of movement. In other words, when the semiconductor device 1000 is rotated, the XY coordinates of the reference bump 1002 is changed by the rotation, and thus the information processing device may identify the amount of movement by considering this change.

For example, the information processing device may first calculate the XY coordinates (hereinafter referred to as alignment coordinates) of the reference bump 1002 of when the posture of the semiconductor device 1000 is rotated to the aligned posture based on the coordinates of the actual reference bump 1002 identified in the bottom image. Then, the information processing device may identify the amount of movement as described above based on the difference between the alignment coordinates in the bottom image and the coordinates of the reference groove 242 in the top image.

In this regard, the amount of rotation may be identified based on the difference between the first angle and the second angle. In this case, the information processing device does not simply identify the difference between the first angle and the second angle as the amount of rotation, but may calculate a rotated angle by considering the actual position of the rotation axis.

Specifically, as described above, the central axis of rotation of the semiconductor device 1000 refers to the central axis of the picker 2000 shaped like a cylinder. In this case, the difference between the first angle and the second angle is calculated by the angle based on the central coordinates of the semiconductor devices 1000, and it is thus necessary to identify the rotated angle based on the central axis of the picker 2000 during actual rotation. To this end, the information processing device may identify the alignment coordinates in the bottom image after calculating the difference between the first angle and the second angle. In this case, the alignment coordinates may be calculated as the coordinates obtained by rotating the coordinates of the reference bump shown in the bottom image as much as the difference between the first angle and the second angle based on the center point of the semiconductor device. Then, the information processing device may calculate an angle between the line connecting the center point (see C1 in FIG. 10) of the bottom image and the alignment coordinates and the line connecting the center point of the bottom image and the actual coordinates of the reference bump R1 shown in the bottom image, and set this angle as the amount of rotation.

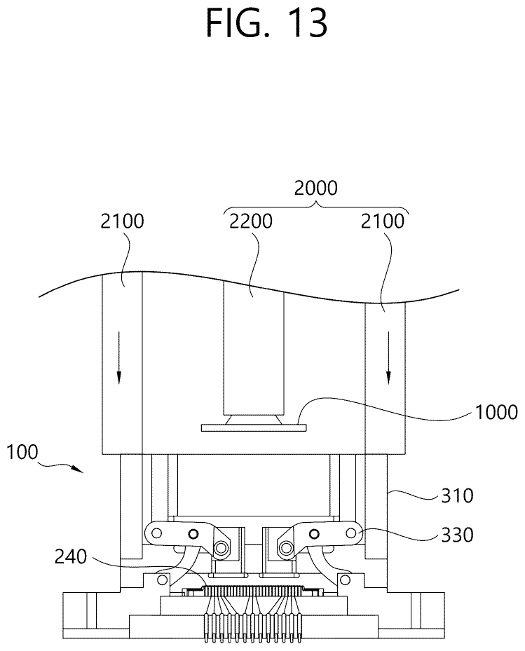

Below, a process of loading the semiconductor device into the insert in the step S1440 where the semiconductor device according to an embodiment of the disclosure is placed in the insert in the aligned posture will be described with reference to FIGS. 13 to 15.

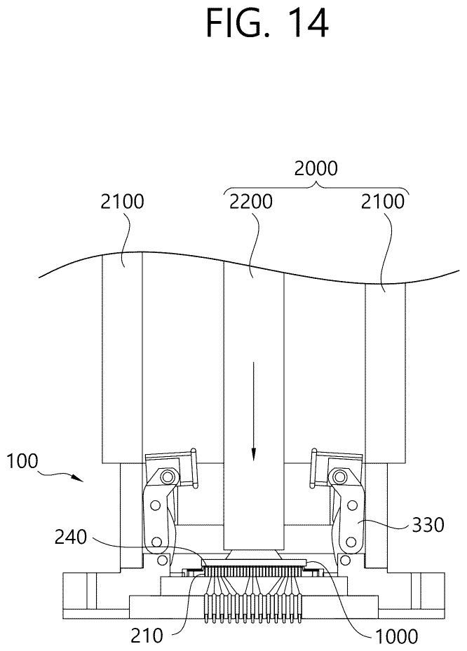

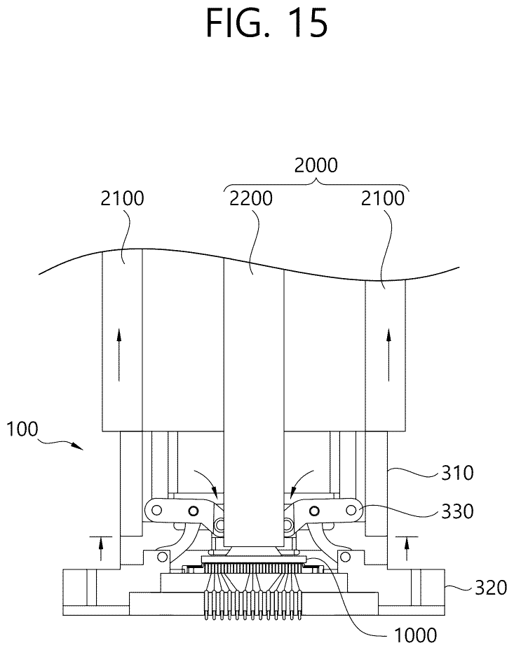

FIG. 13 is a view showing that the picker is in close contact with the upper side of the insert according to an embodiment of the disclosure. In this regard, FIG. 14 is a view showing that the semiconductor device is seated on a floating board after the insert is switched over to an open state according to an embodiment of the disclosure. Further, FIG. 15 is a view showing that the insert is switched over to a closed state after the picker loads the semiconductor device according to an embodiment of the disclosure.

The picker 2000 used in an embodiment of the disclosure may include a push shaft 2100 for pushing the upper block 310, and a suction shaft 2200 coaxially disposed inside the push shaft 2100. In this case, the semiconductor devices 1000 may be picked up and placed based on the pneumatic pressure of the suction shaft 2200. Further, the rotation of the semiconductor device 1000 may be implemented by the rotation of the suction shaft 2200.

The push shaft 2100 may be a tubular member with a hollow interior. With the picker 2000 and the insert 100 aligned coaxially with each other, the push shaft 2100 may be located above the upper block 310 and the suction shaft 2200 may be located above the floating board 240. In this case, the push shaft 2100 and the suction shaft 2200 may be adjustable in height with respect to each other.

Referring to FIG. 13, the state of FIG. 13 shows that the picker 2000 and the insert 100 are in contact with each other as the picker module moves down after the semiconductor device is in the aligned posture. Then, the picker module continues to move down, and the push shaft 2100 presses the upper block 310 as shown in FIG. 14, thereby switching the insert 100 over to the open state.

Simultaneously with or immediately after the open state, the suction shaft 2200 may move down to bring the semiconductor device 1000 into close contact with the floating board 240. Then, when the push shaft 2200 moves up as shown in FIG. 15, the upper block 310 rises and the holding member 330 is switched over back to the closed state. In this case, the suction shaft 2200 is accommodated in a circular groove between the holding members 330 without contact with the holding members 330. When the holding members 330 are switched over to the completely closed state, the negative pressure of the suction shaft 2100 is released and the semiconductor device 1000 is separated from the suction shaft 2100.

Meanwhile, the semiconductor device 1000 may be pressed downward by the pressing force of the holding member 330 and held in position to the insert 100. In this case, the floating board 240 and the semiconductor device 1000 are held in a lowered state by the holding member 330, and the insert terminal 210 is in electrical contact with the fine bumps in this state.

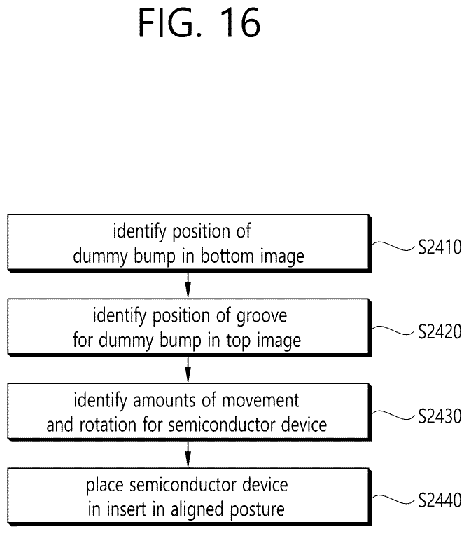

Below, a second embodiment of the step S400 where the picker loads the semiconductor device into the insert will be described with reference to FIGS. 16 to 20. FIG. 16 is a flowchart for describing a second embodiment of a step where “a picker loads a semiconductor device into an insert” included in a method of loading the semiconductor device with fine bumps into the insert according to an embodiment of the disclosure. To avoid redundant description, the description of the same parts as those of the first embodiment will be simplified.

In this case, the method according to the second embodiment may also be performed after performing the same or similar steps of by the picker, picking the semiconductor device (S100); by the first vision module, capturing the bottom image of the semiconductor device (S200); by the second vision module, capturing the top image of the insert (S300); and by the picker, loading the semiconductor device into the insert (S400).

The biggest difference between the first and second embodiments is that not the fine bumps and the guide groove but a separately provided dummy bump and a groove for the dummy bump are used as references for aligning the semiconductor device with the insert.

In this case, the dummy bump may be a bump formed separately from the fine bump in the semiconductor device. Further, the dummy bump may not be configured for signal transmission of the semiconductor device, but may simply be formed on the bottom of the semiconductor device for positioning purposes. In this case, to ease the positioning, the dummy bump may be provided to be larger than the fine bump. In this case, the position and number of dummy bumps may be varied depending on a user's convenience like those of the reference bump.

The groove for the dummy bump may be a groove formed to accommodate the dummy bump on the floating board. The groove for the dummy bump is simply for accommodating and aligning the dummy bump, and does not include an insert terminal placed therein. Like the dummy bump, the groove for the dummy bump may be formed to be larger than the guide groove. Further, like the reference groove, the position and number of grooves for the dummy bump may be formed to correspond to the position and number of dummy bumps.

Below, continuing the description with reference to FIG. 16, the step where the picker loads the semiconductor device into the insert according to the second embodiment of the disclosure may include the steps of identifying the position of the dummy bump in the bottom image (S2410), identifying the position of the groove for the dummy bump in the top image (S2420), identifying the amounts of movement and rotation for the semiconductor device (S2430), and placing the semiconductor device in the insert in the aligned posture.

In the step S2410 where the position of the dummy bump is identified in the bottom image, the position of the dummy bump shown in the bottom image is identified. In this case, the position and number of dummy bumps formed on the semiconductor device may be adjusted appropriately by a user considering the shape of the semiconductor device and a recognition rate for the dummy bump.

For example, the dummy bump may be formed outside an area where the fine bumps are concentrated on the bottom of the semiconductor device. Typically, the fine bumps formed on the semiconductor device are located close together. The dummy bump may be formed outside the outermost bump among the concentrated bumps. This is to prevent the dummy bump from interfering with the electrical contact between the fine bumps and the insert terminals by separating separate the dummy bump at a long distance from the fine bumps. Meanwhile, the dummy bump may be removed from the semiconductor device when the test is complete.

Meanwhile, a plurality of dummy bumps may be formed. In this case, the information processing device may identify the number of dummy bumps in the bottom image. Although there may be various alternative examples, the plurality of dummy bumps may be formed one at each corner of the semiconductor device. This may be to prevent the semiconductor device from tilting to one side as the dummy bump is inserted in the groove for the dummy bump.

Meanwhile, to improve the recognition rate for the dummy bump in the step S2410 where the position of the dummy bump is identified in the bottom image, the dummy bump may be formed in a color distinct from those of the semiconductor device and the fine bump.

Further, to improve the recognition rate for the dummy bump in the step S2410 where the position of the dummy bump is identified in the bottom image, the dummy bump may be formed to have a shape different from that of the fine bump when viewed from above.

For example, the dummy bump may have an upper portion larger than a lower portion, and may have a cross-section different than that of the fine bump. In this regard, the lower portion of the dummy bump may be shaped to correspond to the shape of the fine bump. This is not only to distinguish the dummy bump from the fine bump on the bottom image due to the shape of the upper portion but also to align the fine bumps with the guide groove by the dummy bump. In other words, the dummy bump has the same distal end shape as the fine bump, and thus the alignment between the dummy bump and the groove for the dummy bump has accuracy for aligning the fine bump with the guide groove. In this case, based on the size of the distal end, the dummy bump may be used in the alignment of the semiconductor device having a fine pitch of 0.01 to 0.02 mm.

Further, to improve the recognition rate for the dummy bump in the step S2410 where the position of the dummy bump is identified in the bottom image, the dummy bump may be formed to be larger than the fine bump. Specifically, the maximum diameter and protruding height of the dummy bump may be larger than those of the fine bump. Likewise, the bottom shape of the dummy bump may correspond to that of the fine bump. Therefore, in the process of seating the semiconductor device, the dummy bump may be accommodated in the groove for the dummy bump before the fine bump is accommodated in the guide groove. Thus, in the floating board, the position of the guide groove may be first aligned by the dummy bump.

In the step S2410 where the position of the dummy bump is identified in the bottom image, the information processing device recognizes the reference bump in the bottom image, thereby identifying the actual position of the semiconductor device. In other words, in this embodiment, the position of the semiconductor device may be specified through the position of the dummy bump. In this case, an algorithm for recognizing a specific subject in an image has been already disclosed, and therefore descriptions thereof will be omitted.

Meanwhile, when multiple dummy bumps are set to be recognized, the information processing device may process the subsequent steps based on only the recognized dummy bumps even though some of the dummy bumps are not recognizable in the bottom image. Further, even if any of the recognized dummy bumps is incorrectly recognized, the information processing device may ignore information about the incorrectly recognized dummy bump and process the subsequent steps based on the correctly recognized dummy bumps.

Whether the dummy bump was recognized incorrectly may be identified, for example, based on a distance from other members. For example, if the distance from the outer boundary of the semiconductor device, the nearest fine bump or other feature point to the dummy bump has previously been recorded in the information processing device, the information processing device may identify that only the dummy bumps located within a predetermined distance range from such a reference point have been correctly recognized. On the other hand, if the recognized dummy bumps are located outside the predetermined distance range, the information processing device may ignore those dummy bumps.

As another example, information about a distance from the central point of the semiconductor device to the point where the dummy bump is located may be recorded in the information processing device. In this case, if the distance between the actually recognized dummy bump and the central point differs from the recorded distance information by a predetermined value, it may be identified that the dummy bump has been recognized incorrectly.

In the step S2420 where the position of the groove for the dummy bump is identified in the top image, the position of the groove for the dummy bump shown in the top image is identified. In this step, the information processing device recognizes the groove for the dummy bump in the top image and identifies the actual position of the insert. In other words, according to this embodiment, the location of the insert may be specified based on the position of the groove for the dummy bump. In this case, identifying the position of the groove for the dummy bump inside the insert or floating board in the top image may be achieved by the known algorithm like identifying the position of the dummy bump in the bottom image, and thus redundant descriptions thereof will be omitted.

The information processing device is set to find the dummy bump and the groove for the dummy bump of the corresponding number, in which case, if there is a groove for the dummy bump that is also incorrectly recognized, it may be ignored. Further, the suitability for recognition of the groove for the dummy bump may be identified through the pre-recorded distance between the groove for the dummy bump and the center point of the floating board or the distance between the groove for the dummy bump and the feature point to another specific member of the insert.

In this case, the information processing device may identify only the locations of the groove for the dummy bumps corresponding to the dummy bumps recognized as suitable. If there is no reference groove corresponding to the dummy bump suitably recognized in the previous step among the groove for the dummy bumps recognized in this step, the step S300 of capturing the top image may be performed again.

In this case, the dummy bump and the groove for the dummy bump that correspond to each other may be identified based on comparison between the position of the dummy bump with respect to the central coordinates of the semiconductor device shown in the bottom image and the position of the groove for the dummy bump with respect to the central coordinates of the floating board shown in the top image. For example, the dummy bump and the groove for the dummy bump spaced apart by similar locations from the central coordinates may be identified to correspond to each other.

In the step S2430 where the amounts of movement and rotation for the semiconductor device are identified, the amounts of movement and rotation are identified based on the position of the dummy bump and the position of the groove for the dummy bump. In this step, the amount of movement for the picker may be identified based on the coordinates of the dummy bump on the bottom image and the coordinates of the groove for the dummy bump on the top image. Further, in this step, it is determined how much the semiconductor device should to be further rotated to reach the aligned posture with the insert, based on the posture of the semiconductor device on the bottom image and the posture of the insert on the top image. In other words, the amount of rotation may refer to an angle by which the semiconductor device should be relatively rotated so that the angle of the groove for the dummy bump to the central coordinates of the insert on the top image and the angle of the dummy bump to the center of the semiconductor device can be equal to each other.

In the step S2440 in which the semiconductor device is placed in the insert in the aligned posture, the picker transports the semiconductor device above the insert based on the identified amount of movement and rotation, rotates the semiconductor device, and then moves the semiconductor device downward to be loaded into the insert. In this case, as described above, the picker may be first rotated by the amount of rotation and then moved by the amount of movement, and not the picker but the stage supporting the sub-tray may be rotated.

In other words, in this embodiment, the actual position and actual posture of the semiconductor device are specified based on the coordinates in the image of the dummy bump shown in the bottom image, and the actual position and posture of the floating board are specified based on the coordinates in the image of the groove for the dummy bump shown in the top image.

In other words, the coordinates of the dummy bump in the bottom image make it possible to identify the coordinates of that dummy bump and the coordinates of the semiconductor device having the dummy bump in real space. Further, on the bottom image, the angle of the dummy bump to the center of the semiconductor device makes it possible to identify the posture of the semiconductor device currently picked up by the picker.

Likewise, the coordinates of the groove for the dummy bump in the top image make it possible to identify the coordinates of the groove for the dummy bump and the coordinates of the floating board in real space. Further, on the top image, the angle of the groove for the dummy bump to the center of the floating board makes it possible to identify the posture of the insert located at the current placing position.

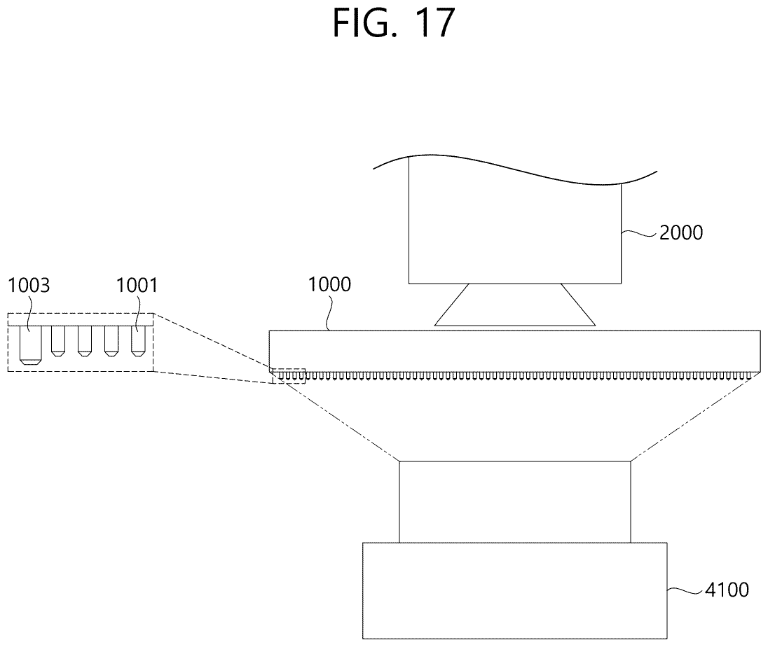

Below, continuing the description with reference to FIG. 17, FIG. 17 is a view showing that a bottom image is captured by a first vision module at a first capturing location, in the step where the picker loads the semiconductor device into the insert according to the second embodiment of the disclosure.

As shown in FIG. 17, a plurality of fine bumps 1001 protrude from the bottom of the semiconductor device 1000, and a dummy bump 1003 may be formed outside the outermost fine bumps 1001. However, the position of the dummy bump 1003 is not necessarily limited to this case, but may be formed between the fine bumps 1001 in some cases.

While the semiconductor device 1000 is held on the picker 2000, the bottom of the semiconductor device 1000 may be captured by the first vision module 4100. In this case, the first vision module 4100 may use coaxial lighting and/or ring lighting to illuminate the bottom of the semiconductor devices 1000 by light, in order to prevent shadows from occurring in the bottom image due to a height difference caused by the fine bumps 1001 on the bottom of the semiconductor device 1000. Thus, an image obtained in the step S200 where the first vision module captures the bottom image of the semiconductor device may have a minimum dark area due to the shadows in the image. This lighting may have an effect on ensuring a good recognition rate of the dummy bump 1003.

In this case, unlike the first embodiment, in the second embodiment, the fine bumps 1001 are not required to be clearly shown on the bottom image. Therefore, in the second embodiment, in some cases, the lighting module may be configured to illuminate only an area where the dummy bump 1003 is located on the bottom of the semiconductor device 1000, rather than illuminating an area where the fine bumps 1001 are located.

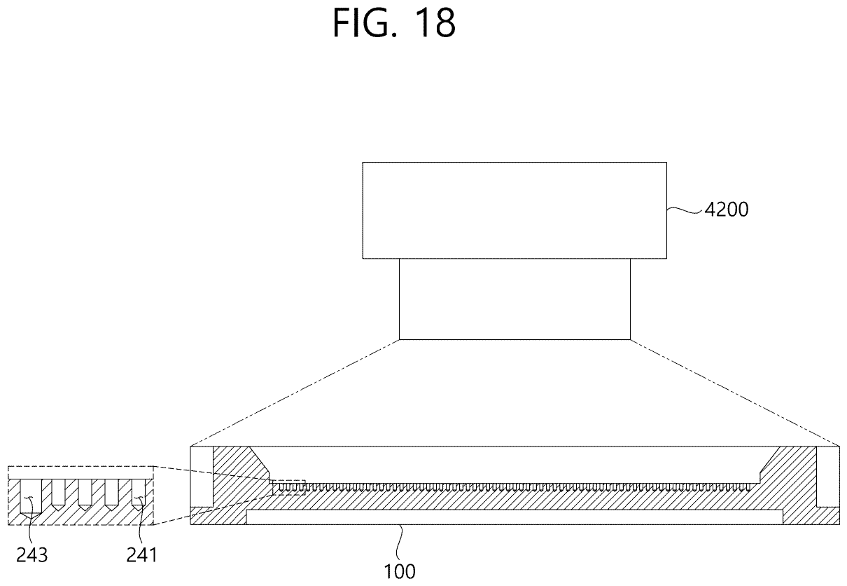

Meanwhile, FIG. 18 is a view showing that a top image is captured by a second vision module at a second capturing location, in the step where the picker loads the semiconductor device into the insert according to the first embodiment of the disclosure.

As shown in FIG. 18, the plurality of guide grooves 241 are formed on the upper surface of the floating board 240 of the insert 100, and a groove 243 for the dummy bump may be formed at a position corresponding to the dummy bump. The groove 243 for the dummy bump may be formed more largely and deeply than the guide groove 241 to accommodate the dummy bump. In this case, like the relationship between the dummy bump and the fine bump, the lower portion of the groove 243 for the dummy bump may be formed to have a size and an inner diameter which are similar to those of the guide groove 241.

Meanwhile, in the step S300 where the second vision module captures the top image of the insert, the second vision module 4200 may capture the top image while illuminating the insert 100 so that the groove 243 for the dummy bump can be clearly shown on the top image. For example, the second vision module 4200 may use coaxial lighting and/or ring lighting to illuminate the upper surface of the floating board 240. Thus, the groove 243 for the dummy bump may appear clearly in the top image without being hidden by shadows or the like. This lighting may have an effect on ensuring a good recognition rate for the groove 243 for the dummy bump.

In this case, unlike the first embodiment, in the second embodiment, the guide grooves 241 are not required to be clearly shown on the top image. Therefore, in the second embodiment, in some cases, the lighting module may be configured to illuminate only an area where the groove 243 for the dummy bump is located on the top of the insert 100, rather than illuminating the guide groove 241.

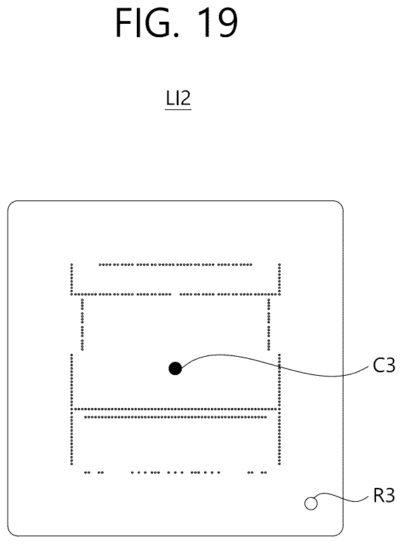

Below, an example of how to identify the actual position and posture of the semiconductor device based on the dummy bump will be described with reference to FIG. 19. FIG. 19 is a view conceptually showing a captured bottom image in the step where the picker loads the semiconductor device into the insert according to the second embodiment of the disclosure.

As described above, the information processing device may identify the actual position and posture of the semiconductor device based on a position of the dummy bump R3 shown in a bottom image LI2. A center point C3 of the bottom image LI3 has the same X and Y coordinates as those of the optical axis of the first vision module. Further, the coordinates of the bottom image LI2 always have the same X and Y coordinates in real space. This is because the first capturing location is always the same. Therefore, the coordinates the position of the dummy bump R3 has on the bottom image LI2 allow the coordinates of the semiconductor device to be identified in real space.

In other words, according to the disclosure, only the coordinates of the dummy bump R3, or only the location within the image of the mark identifiable by the separately prepared information processing device is enough to identify the actual position of the semiconductor device.

Meanwhile, the information processing device may recognize the first angle, which the dummy bump R3 has with respect to a predetermined reference point shown in the bottom image LI2, as the actual posture of the semiconductor device. For example, the reference point may be set as the central coordinates of the semiconductor device shown in the bottom image LI2. In this case, the first angle may refer to an angle between a straight line connecting the coordinates of the dummy bump R3 and the central coordinates of the semiconductor device and a straight line having a slope of ‘0’. For example, the first angle may be identified based on the slope of a straight line connecting the coordinates of the dummy bump R3 and the central coordinates of the semiconductor device.

In this case, the central coordinates of the semiconductor device may be identified by publicly known methods. For example, the information processing device may recognize the boundary points of the semiconductor device shown in the bottom image LI2 and average the coordinates of the corresponding points, thereby obtaining the central coordinates. Alternatively, the semiconductor device may be marked with a separate mark to identify the central coordinates.

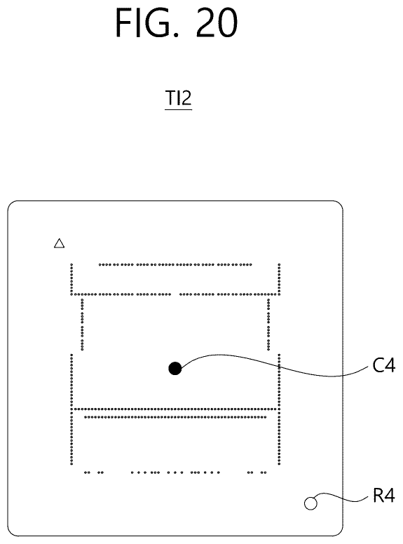

Below, an example of how to identify the actual position and posture of the insert based on the groove for the dummy bump will be described with reference to FIG. 20. FIG. 20 is a view illustratively showing a captured top image in the step where the picker loads the semiconductor device into the insert according to the second embodiment of the disclosure.

The information processing device may identify the actual position and posture of the insert based on the position of the groove R4 for the dummy bump shown in the top image TI2. The center point C4 of the top image TI2 has the same X and Y coordinates as the optical axis of the second vision module. Further, the coordinates of the top image TI2 always have the same X and Y coordinates in real space. This is because the second capturing location is always the same. Therefore, the coordinates the position of the groove R4 for the dummy bump has on the top image TI2 allow the coordinates of the insert to be identified in real space.

In other words, according to the disclosure, only the coordinates of the groove for the dummy bump R4 or only the location within the image of the mark identifiable by the separately provided information processing device is enough to identify the actual position of the insert.

Meanwhile, the information processing device may recognize the second angle, which the groove R4 for the dummy bump has with respect to a predetermined reference point shown in the top image TI2, as the actual posture of the insert. For example, the reference point may be set as the central coordinates of the insert and/or floating board (hereinafter referred to as the central coordinates of the insert) shown in the top image. In this case, the second angle may refer to an angle between a straight line connecting the coordinates of the groove R4 for the dummy bump and the central coordinates of the insert and a straight line having a slope of ‘0’. For example, the second angle may be identified based on the slope of a straight line connecting the coordinates of the groove R4 for the dummy bump and the central coordinates of the insert.

In this case, the central coordinates of the insert may be identified by publicly known methods. For example, the information processing device may recognize the boundary points of the insert and/or floating board shown in the top image TI2 and average the coordinates of the corresponding points, thereby obtaining the central coordinates. Alternatively, the insert and/or the floating board may be marked with separate marks to identify the central coordinates.

According to the embodiments of the disclosure, the semiconductor device may be loaded into the insert after identifying the actual position of the semiconductor device and the actual position of the insert through the corresponding structures between the reference bump and the reference groove or the corresponding structure between the dummy bump and the groove for the dummy bump. Thus, it is advantageous to load the semiconductor device into the insert in an appropriate posture.

Specifically, if the semiconductor device having the fine bumps arranged at the fine pitch where the spacing between the terminals is very narrow is slightly distorted while being seated in the insert or the socket, the bumps may not be properly accommodated in the corresponding grooves. In this case, of course, the test may not proceed smoothly, and the fine bumps is likely to be damaged by contact with other parts than the groove. In this regard, according to the disclosure, the semiconductor device is properly aligned with the insert based on the fine bump and the guide groove for the fine bump or based on the dummy bump capable of the alignment at the fine pitch, thereby accurately seating the semiconductor device on the insert. In this case, the alignment accuracy may be further improved by increasing the number of reference bumps and dummy bumps.

Further, according to the disclosure, after the semiconductor device is accommodated in the insert in the aligned posture (i.e., the posture in which the fine bumps can be accommodated in the guide grooves, respectively), the holding member holds the semiconductor device, and the insert and the semiconductor device are electrically connected. The semiconductor device moves inside the handler while being loaded into the insert, and its position inside the insert is fixed even when undergoing the testing. Therefore, according to the disclosure, after the semiconductor device is initially loaded into the insert, the insert or tray is used when moving or testing the semiconductor device. Accordingly, in the case of moving and testing the semiconductor device after loading, the burden of securing precise alignment is significantly reduced.

Meanwhile, according to the second embodiment of the disclosure, the dummy bump first comes into contact with the insert first, and it is thus advantageous to minimize the load applied to the fine bumps compared to that of the first embodiment. In other words, according to the second embodiment, the floating board is primarily shaken by the dummy bump and then the fine bumps are secondarily accommodated in the guide groove, thereby making the fine bumps and the guide groove be in contact with each other in a more aligned state.

According to the embodiments of the disclosure, the effects are at least as follows.

The picker can place a device having a fine pitch in the exact position of the insert. Thus, the reliability of test results may be improved in testing a semiconductor product having a fine pitch.

Further, a semiconductor product is automatically loaded and secured in the correct position inside the insert, thereby efficiently shortening the time required for aligning the semiconductor product having the fine pitch.

The effects of the disclosure are not limited to those described above, and various other effects are included in the foregoing description

A person having ordinary knowledge in the art to which the disclosure pertains may understood that the disclosure may be embodied in other specific forms without changing technical spirit or essential features. Accordingly, the embodiments described above are illustrative and not restrictive in all aspects. The scope of the disclosure is defined by the appended claims rather than the foregoing detailed description, and all changes or modifications derived from the meaning and scope of the appended claims and their equivalents are construed as falling within the scope of the disclosure.

*Reference Numerals

| | |
|---|---|
| 1: test tray | |
| 10: sub tray | 100: insert |
| 200: electric contact portion | |
| 210: insert terminal | |
| 220: circuit board | 230: holding board |
| 231: external terminal | 240: floating board |
| 241: guide groove | 250: terminal board |
| 310: upper block | 320: lower block |
| 330: holding member | 1000: semiconductor device |
| 2000: picker | 3000: pickup module |
| 4100: first vision module | |
| 4200: second vision module | |

What is claimed is:

1. A method of loading a semiconductor, which has a plurality of fine bumps on a bottom surface, into an insert formed with guide grooves on a top surface to accommodate the fine bumps, respectively, the method comprising:
by a first vision module, capturing a bottom image of the semiconductor device picked up by a picker;
by a second vision module, capturing a top image of the insert; and
by the picker, loading the semiconductor device into the insert, based on the bottom image and the top image.

2. The method of claim 1, wherein the loading the semiconductor device into the insert comprises:
identifying a position of a reference bump among the plurality of fine bumps in the bottom image;
identifying a position of a reference groove to accommodate the reference bump therein among the plurality of guide grooves in the top image;
identifying the amounts of movement and rotation for the semiconductor device, based on the position of the reference bump and the position of the reference groove; and
moving the semiconductor device above the insert based on the identified amount of movement, and placing the semiconductor device in the insert in an aligned posture based on the identified amount of rotation.

3. The method of claim 2, wherein
in the identifying the position of the reference bump, an actual position and posture of the semiconductor device are identified based on the position of the reference bump on the bottom image, and
in the identifying the position of the reference groove, an actual position and posture of the insert to load the semiconductor device are identified based on the position of the reference groove on the top image.

4. The method of claim 3, wherein
in the identifying the position of the reference bump, the actual position of the semiconductor device is identified based on the position of the reference bump on the bottom image and an accurately set capturing location of the first vision module,
in the identifying the position of the reference groove, the actual position of the insert is identified based on the position of the reference groove on the top image and an accurately set capturing location of the second vision module, and
in the identifying the amounts of movement and rotation for the semiconductor device, the amount of movement for the semiconductor device is identified based on difference in coordinates between the actual position of the semiconductor device and the actual position of the insert.

5. The method of claim 3, wherein
in the identifying the position of the reference bump, the actual posture of the semiconductor device is identified based on a first angle of the reference bump shown in the bottom image to a reference point on the bottom image,
in the identifying the position of the reference groove, the actual posture of the insert is identified based on a second angle of the reference groove shown in the top image to a reference point on the top image, and
in the identifying the amount of movement and rotation for the semiconductor device, the amount of rotation for the semiconductor device is identified based on difference between the first angle and the second angle.

6. The method of claim 1, wherein the loading the semiconductor device into the insert comprises:
identifying a position of a dummy bump formed separately from the plurality of fine bumps in the bottom image;
identifying a position of a groove for the dummy bump formed separately from the plurality of guide grooves to accommodate the dummy bump in the top image;
identifying the amount of movement and rotation for the semiconductor device based on the position of the dummy bump and the position of the groove for the dummy bump; and
moving the semiconductor device above the insert based on the identified amount of movement, and placing the semiconductor device in the insert in an aligned posture based on the identified amount of rotation.

7. The method of claim 6, wherein
in the identifying the position of the dummy bump, an actual position and posture of the semiconductor device is identified based on the position of the dummy bump on the bottom image, and
in the identifying the position of the groove for the dummy bump, an actual position and posture of the insert to load the semiconductor device is identified based on the position of the groove for the dummy bump on the top image.

8. The method of claim 7, wherein the dummy bump is formed to be larger than the fine bump, and comprises a lower portion shaped corresponding to the shape of the fine bump.

9. The method of claim 7, wherein the dummy bump is located outside an area where the plurality of fine bumps are located on the bottom surface of the semiconductor device.

10. The method of claim 1, further comprising picking up a plurality of semiconductor devices by a plurality of pickers arranged in a predetermined array.

11. The method of claim 10, wherein
in the capturing the bottom image by the first vision module, a bottom surface of a representative semiconductor device picked up by a representative picker among the plurality of pickers is captured, and
in the identifying the amounts of movement and rotation for the semiconductor device, the amounts of movement and rotation for the remaining semiconductor devices is identified based on the amount of movement and rotation for the representative semiconductor device.

12. The method of claim 1, wherein in the capturing the bottom image by the first vision module, the bottom image is captured while lighting illuminates the bottom surface of the semiconductor device.

13. The method of claim 1, wherein in the capturing the top image by the second vision module, the top image is captured while lighting illuminates the top surface of the insert.

14. The method of claim 1, wherein in the placing the semiconductor device in the insert in the aligned posture, a holding member of the insert, by pressing the placed semiconductor device downward, holds the position of the semiconductor device.

15. The method of claim 14, wherein in the placing the semiconductor device in the insert in the aligned posture, a floating board formed with the guide groove and the semiconductor device are pressed to downward by the holding member, and an insert terminal accommodated inside the guide groove is in contact with the fine bump moved downward.
